(19) United States
(12) Patent Application Publication
(10) Pub. No.: US 2023/0064594 A1
(43) Pub. Date: Mar. 2, 2023

(54) MEMORY, MEMORY SYSTEM, OPERATION METHOD OF MEMORY AND OPERATION METHOD OF MEMORY SYSTEM

(71) Applicant: SK hynix Inc., Gyeonggi-do (KR)

(72) Inventors: Won Kyung CHUNG, Gyeonggi-do (KR); Saeng Hwan KIM, Gyeonggi-do (KR)

(21) Appl. No.: 17/730,367

(22) Filed: Apr. 27, 2022

Related U.S. Application Data
(60) Provisional application No. 63/239,401, filed on Aug. 31, 2021.

(30) Foreign Application Priority Data
Jan. 10, 2022 (KR) 10-2022-0003359

(51) Int. Cl. G06F 3/06

(52) U.S. Cl. CPC G06F 3/0644; G06F 3/0659; G06F 3/0604; G06F 3/0673

(57) ABSTRACT

A method for operating a memory includes: activating a row which is selected based on a row address among a plurality of rows; receiving a counting command while the selected row is activated; reading a number of accesses from memory cells of particular columns of the selected row in response to the counting command; increasing the number of accesses; and writing the increased number of accesses into the memory cells of the particular columns of the selected row.

### CROSS-REFERENCE TO RELATED APPLICATIONS

The present application claims priority to U.S Provisional Patent Application No. 63/239,401, filed on Aug. 31, 2021 and Korean Patent Application No. 10-2022-0003359, filed on Jan. 10, 2022, which are both incorporated herein by reference in their entirety.

### BACKGROUND

### 1. Field

Various embodiments of the present invention relate to a memory and a memory system including the same.

### 2. Description of the Related Art

As the degree of integration of a memory increases, the spacing between a plurality of word lines included in the memory decreases. As the spacing between word lines decreases, the coupling effect between the neighboring word lines increases.

Moreover, whenever data is input to or output from a memory cell, a word line toggles between an active state and an inactive state. As the coupling effect between the neighboring word lines increases, the data in the memory cell coupled to a word line which is disposed adjacent to a frequently activated word line may be damaged. This phenomenon is referred to as Row Hammering. Since the data of a memory cell is damaged before the memory cell is refreshed due to word line disturbance, there may be an issue with the integrity of the data.

FIG. 1 is a view illustrating row hammering. FIG. 1 shows a portion of a cell array included in a memory.

In FIG. 1, ‘WLL’ may correspond to a word line with a large number of activations, and ‘WLL−1’ and ‘WLL+1’ may be word lines disposed adjacent to ‘WLL’, that is, word lines disposed adjacent to the word line with a large number of activations. Also, ‘CL’ may indicate a memory cell that is coupled to the ‘WLL’, and ‘CL−1’ may indicate a memory cell that is coupled to the ‘WLL−1’, and ‘CL+1’ may indicate a memory cell that is coupled to the ‘WLL+1’. Each memory cell may include a cell transistor TL, TL−1, and TL+1 and a cell capacitor CAPL, CAPL−1, and CAPL+1.

When ‘WLL’ is activated or deactivated in FIG. 1, the voltages of ‘WLL−1’ and ‘WLL+1’ may rise or fall due to the coupling effect occurring between the ‘WLL’ and the ‘WLL−1’ and ‘WLL+1’, also affecting the amount of charges in the cell capacitors CL−1 and CL+1. Therefore, when the ‘WLL’ is frequently activated and the ‘WLL’ toggles between an activated state and a deactivated state, the change in the amount of charges stored in the cell capacitors CAPL−1 and CAPL+1 that are included in the ‘CL−1’ and the ‘CL+1’ may increase and the data in the memory cell may be deteriorated.

Also, the electromagnetic wave generated when the word line toggles between the activated state and the deactivated state may damage the data by introducing electrons into the cell capacitor of the memory cell coupled to a neighboring word line or by leaking electrons from the cell capacitor.

A method that is mainly used for addressing the issue of row hammering, includes a method of detecting a row (word line) that has been activated multiple times and refreshing the rows neighboring the row that has been activated multiple times.

### SUMMARY

Embodiments of the present invention are directed to a technology for increasing the defending capability of a memory against row hammer attacks.

In accordance with an embodiment of the present invention, a method for operating a memory includes: activating a row which is selected based on a row address among a plurality of rows; receiving a counting command while the selected row is activated; reading a number of accesses from memory cells of particular columns of the selected row in response to the counting command; increasing the number of accesses; and writing the increased number of accesses into the memory cells of the particular columns of the selected row.

In accordance with another embodiment of the present invention, a method for operating a memory includes: activating a row which is selected based on a row address among a plurality of rows; receiving a read command and a particular column address while the selected row is activated; reading a number of accesses from memory cells of particular columns of the selected row in response to the read command and the particular column address; increasing the number of accesses; and writing the increased number of accesses into the memory cells of the particular columns of the selected row.

In accordance with another embodiment of the present invention, a method for operating a memory includes: activating a row which is selected based on a row address among a plurality of rows; receiving a write command and a particular column address while the selected row is activated; reading a number of accesses from memory cells of particular columns of the selected row in response to the write command and the particular column address; increasing the number of accesses; and writing the increased number of accesses into the memory cells of the particular columns of the selected row.

In accordance with another embodiment of the present invention, a memory includes: a cell array including memory cells that are arranged in a plurality of rows and a plurality of columns; a row circuit suitable for selecting and activating one row among the plurality of rows of the cell array during an active operation; a column circuit suitable for reading a number of accesses from memory cells of particular columns of the selected row in response to a counting command, and writing an updated number of accesses to the memory cells of the particular columns of the selected row; and an access operation circuit suitable for receiving the number of accesses which is read from the column circuit, increasing the number of accesses, and transferring the increased number of accesses to the column circuit as the updated number of accesses.

In accordance with another embodiment of the present invention, a memory includes: a cell array including memory cells that are arranged in a plurality of rows and a plurality of columns; a row circuit suitable for selecting and activating one row among a plurality of rows of the cell array during an active operation; a column circuit suitable for reading a number of accesses from memory cells of particular columns of the selected row in response to a read command and a particular column address, and writing an updated number of accesses into the memory cells of the particular columns of the selected row; and an access operation circuit suitable for receiving the number of accesses which is read from the column circuit, increasing the number of accesses, and transferring the increased number of accesses to the column circuit as the updated number of accesses.

In accordance with another embodiment of the present invention, a memory includes: a cell array including memory cells that are arranged in a plurality of rows and a plurality of columns; a row circuit suitable for selecting and activating one row among a plurality of rows of the cell array during an active operation; a column circuit suitable for reading a number of accesses from memory cells of particular columns of the selected row in response to a write command and a particular column address, and writing an updated number of accesses into the memory cells of the particular columns of the selected row; and an access operation circuit suitable for receiving the number of accesses which is read from the column circuit, increasing the number of accesses, and transferring the increased number of accesses to the column circuit as the updated number of accesses.

In accordance with another embodiment of the present invention, a method for operating a memory system includes: transferring an active command and a row address from a memory controller to a memory; activating, in the memory, a row corresponding to the row address; transferring a counting command from the memory controller to the memory while the row is activated; and increasing and writing a number of accesses to the row in the memory in response to the counting command.

In accordance with another embodiment of the present invention, a method for operating a memory system includes: transferring an active command and a row address from a memory controller to a memory; activating, in the memory, a row corresponding to the row address; transferring a read command and a particular column address from the memory controller to the memory while the row is activated; and increasing and writing a number of accesses to the row in the memory in response to the read command and the particular column address.

In accordance with another embodiment of the present invention, a method for operating a memory system includes: transferring an active command and a row address from a memory controller to a memory; activating, in the memory, a row corresponding to the row address; transferring a write command and a particular column address from the memory controller to the memory while the row is activated; and increasing and writing a number of accesses to the row in the memory in response to the read command and the particular column address.

In accordance with another embodiment of the present invention, a memory system includes: a memory controller suitable for directing an active operation and directing a counting operation during the active operation; and a memory suitable for activating one row among a plurality of rows in response to the direction of the active operation, and increasing and writing a number of accesses to the row in response to the direction of the counting operation.

In accordance with another embodiment of the present invention, a memory includes: a memory cell array of rows each including one or more memory cells configured to store therein a number of accesses to the row; and a control circuit configured to: activate a selected one of the rows, update the number stored in the selected row in response to a command, and perform, when the updated number becomes a threshold or greater, a refresh operation on one or more adjacent rows of the selected row.

### BRIEF DESCRIPTION OF THE DRAWINGS

FIG. 1 is a circuit diagram illustrating row hammering.

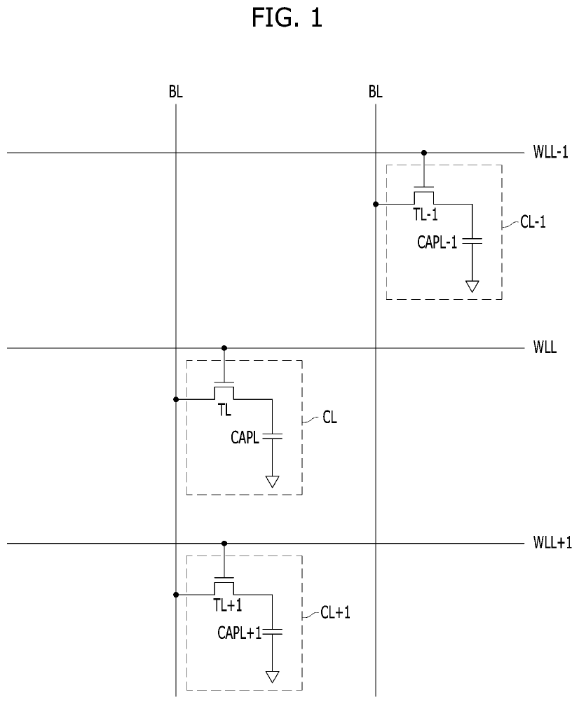

FIG. 2 is a block diagram illustrating a memory system 200 in accordance with an embodiment of the present invention.

FIG. 3 is a block diagram illustrating a memory 250 shown in FIG. 2 in accordance with an embodiment of the present invention.

FIG. 4 is a flowchart describing an operation of the memory system 200 shown in FIG. 2 in accordance with an embodiment of the present invention.

### DETAILED DESCRIPTION

Various embodiments of the present invention will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Throughout this disclosure, like reference numerals refer to like parts throughout the various figures and embodiments of the present invention.

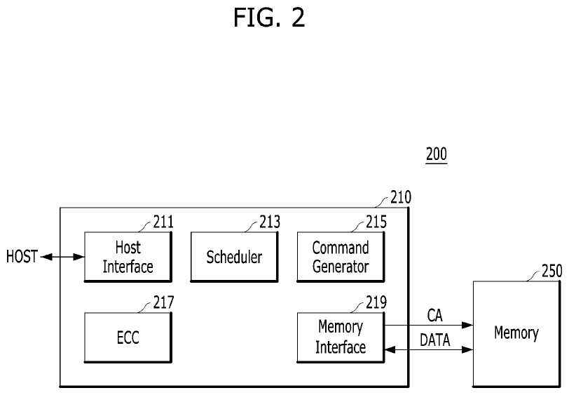

FIG. 2 is a block diagram illustrating a memory system 200 in accordance with an embodiment of the present invention.

Referring to FIG. 2, the memory system 200 may include a memory controller 210 and a memory 250.

The memory controller 210 may control the operation of the memory 250 according to a request from a host HOST. The host may include a Central Processing Unit (CPU), a Graphic Processing Unit (GPU), an Application Processor (AP), and the like. The memory controller 210 may include a host interface 211, a scheduler 213, a command generator 215, an error correction circuit 217, and a memory interface 219. The memory controller 210 may be included in a processor such as a CPU, GPU, or AP. In this case, the host HOST may represent the structure other than the memory controller 210 in the internal structures of the processor. For example, when the memory controller 210 is included in a CPU, the host HOST of the figure may represent the other constituent elements except for the memory controller 210 in the CPU.

The host interface 211 may be an interface between the memory controller 210 and the host HOST.

The scheduler 213 may determine the order of requests to be directed to the memory 250 among the requests from the host HOST. In order to improve the performance of the memory 250, the scheduler 213 may change the order of requests received from the host HOST and the order of operations to be directed to the memory 250. For example, even though the host HOST requests a read operation of the memory 250 first and then requests a write operation later, the order may be adjusted in such a manner that a write operation is performed before a read operation.

According to the embodiment of the present invention, the memory 250 may perform a counting operation for counting the number of row accesses according to a direction of the memory controller 210, and the scheduler 213 may schedule the counting operation of the memory 250 at every active operation of the memory 250. That is, when one row is activated, it may schedule a one-time counting operation before the activated row is precharged. For example, the scheduler 213 may schedule a sequence of an active operation on the third row 3, a read operation, a write operation, a counting operation, a precharge operation on the third row 3, an active operation on the 100th row 100, a counting operation, a read operation, a precharge operation on the 100th row 100, an active operation on the 53^{rd} row 53, a read operation, a read operation, a counting operation, a write operation and a precharge operation on the 53^{rd} row 53. It may be seen from the example that the scheduler 213 schedules a counting operation once in a section between the active operation of the N^{th} row and the precharge operation of the N^{th} row.

The command generator 215 may generate a command to be applied to the memory 250 according to the order of operations determined by the scheduler 213.

The error correction circuit 217 may detect and correct an error in the data stored in the memory 250. The error correction circuit 217 may generate an error correction code ECC based on the data to be written into the memory 250 during a write operation of the memory 250. The error correction code generated by the error correction circuit 217 may be stored in the memory 250 together with the write data. The error correction circuit 217 may detect an error in the data that are read from the memory 250 based on the error correction code ECC that is read from the memory 250 during a read operation of the memory 250, and when an error is detected, correct the detected error. In FIG. 2, the data DATA transferred/received between the memory controller 210 and the memory 250 may include raw data and the error correction code ECC.

The memory interface 219 may be provided for an interface between the memory controller 210 and the memory 250. A command and an address CA may be transferred from the memory controller 210 to the memory 250 through the memory interface 219, and the data DATA may be transferred/received from the memory controller 210 to the memory 250 through the memory interface 219. The memory interface 219 may also be referred to as a PHY interface.

The memory 250 may perform an operation directed by the memory controller 210. The memory 250 may be a memory requiring a refresh operation. For example, the memory 250 may be a Dynamic Random Access Memory (DRAM) or another type of memory requiring a refresh operation. The memory 250 may perform an active operation, a precharge operation, a read operation, a write operation, a refresh operation, and a counting operation according to a direction of the memory controller 210.

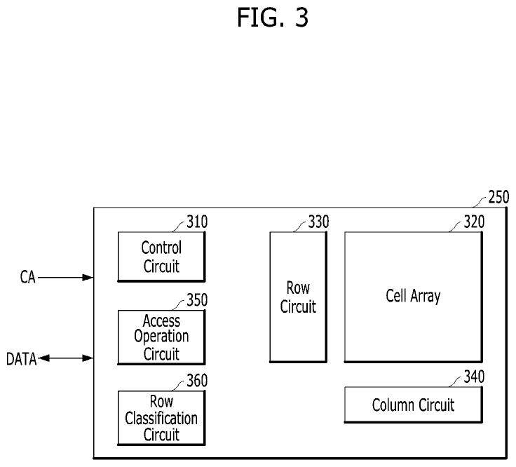

FIG. 3 is a block diagram illustrating the memory 250 shown in FIG. 2 in accordance with an embodiment of the present invention.

Referring to FIG. 3, the memory 250 may include a control circuit 310, a cell array 320, a row circuit 330, a column circuit 340, an access operation circuit 350, and a row classification circuit 360.

The control circuit 310 may control the overall operation of the memory 250. The control circuit 310 may control the internal constituent elements of the memory 250 to perform the operations directed by the command and the address CA, for example, an active operation, a precharge operation, a read operation, a write operation, a refresh operation, and a counting operation.

The cell array 320 may include a plurality of memory cells that are arranged in a plurality of rows and a plurality of columns. In each of the rows, memory cells of N specific columns may be used to store the number of accesses to the corresponding row. When the total number of columns is M, the memory cells of M-N columns in each row may be used to store data, and memory cells of N columns may be used to store the number of accesses to the corresponding row. For example, in the first row, memory cells of the first to (M−N)^{th} columns may be used to store data, and the memory cells of the (m−N_{±}1)^{th} to M^{th} columns may be used to store the number of accesses to the first row. Similarly, in the 103^{rd} row, the memory cells of the first to (M−N)^{th} columns may be used to store data, and the memory cells of columns (M−N+1)^{th} to M^{th} columns may be used to store the number of accesses to the 103^{rd} row. Since the number of columns per row is usually tens of thousands or more, and tens of bits (e.g., 16 bits) are needed to record the number of accesses to the row, tens of thousands or more of memory cells in one row may be used to store data, and only scores of memory cells may be used to store the number of accesses. Although it is described herein that the memory cells of the (M−N+1)th to M^{th} columns in each row are used to store the number of accesses, it will be apparent to those skilled in the art that the locations of the memory cells used to store the number of accesses may be different from this embodiment of the present invention.

The row circuit 330 may perform an active operation of activating a row which is selected based on a row address among the rows of the cell array 320. During the active operation, data of the memory cells of a selected row may be sensed and amplified. Also, the row circuit 330 may refresh the memory cells of the row selected to perform a refresh operation.

The column circuit 340 may write data to or read data from the memory cells of the columns that are selected based on the column address among the columns of a row selected by the row circuit in the cell array 320. Namely, the column circuit 340 may perform an operation of reading or writing data of the memory cells corresponding to the selected row and selected columns in the cell array 320. During a counting operation, the column circuit 340 may read the number of accesses from the memory cells of particular columns for storing the number of accesses, transfer the read number of accesses to the access operation circuit 350, and write the number of accesses which is updated by the access operation circuit 350 back to the memory cells of the particular columns.

The access operation circuit 350 may perform an update by increasing the number of accesses transferred from the column circuit 340 and transfer the updated number of accesses back to the column circuit 340. For example, when the number of accesses to row 6, which is ‘1034’, is transferred from the column circuit 340, the number of accesses may be updated to ‘1035’ and transferred to the column circuit 340.

The row classification circuit 360 checks out whether or not the number of accesses which is updated by the access operation circuit 350 is equal to or greater than a threshold value, and when the updated number of accesses is equal to or greater than the threshold value, the row classification circuit 360 may classify and store the neighboring rows of the corresponding row as rows required to be refreshed. For example, when the updated number of accesses to the 7th row is equal to or greater than a threshold, which is ‘10000’, the row classification circuit 360 may classify and store the neighboring rows of the 7th row, which are the 6th and 8th rows as rows required to be refreshed.

Hereafter, diverse operations of the memory 250 will be described.

Active Operation

An active operation may begin, as an active command and a row address are applied from the memory controller 210 to the memory 250. The row circuit 330 may perform an active operation of selecting and activating a row corresponding to a row address among the rows of the cell array 320. During an active operation, data of the memory cells in the selected row may be sensed and amplified. The active operation may be terminated as the memory controller 210 applies a precharge command to the memory 250. An operation of terminating the active operation may be referred to as a precharge operation.

Write Operation

A write operation may be performed during an active operation. A write operation may begin as the memory controller 210 applies a write command and a column address to the memory 250. Also, during a write operation, write data may be transferred from the memory controller 210 to the memory 250. During a write operation, the column circuit 340 may write the write data into the memory cells of the columns selected based on the column address in the row selected by the row circuit 330. That is, during a write operation, write data may be written into the memory cells selected based on the row address which is input during the active operation and the column address which is input during the write operation.

Read Operation

A read operation may be performed during an active operation. A read operation may begin, as the memory controller 210 applies a read command and a column address to the memory 250. During a read operation, the column circuit 340 may read data from the memory cells of the columns that are selected based on the column address in the row that is selected by the row circuit 330. Also, the read data may be transferred from the memory 210 to the memory controller 250. During a read operation, data may be read from the memory cells selected based on the row address which is input during an active operation and the column address which is input during a read operation, and the read data may be transferred to the memory controller 250.

Counting Operation

A counting operation may be an operation of counting the number of accesses to a row for which an active operation is currently being performed, that is, the number of active operations. Therefore, a counting operation may be performed during an active operation. The counting operation may begin as the memory controller 210 applies a counting command to the memory 250. When a counting command is applied, the column circuit 340 may read the number of accesses from the memory cells of N particular columns of the row which is selected by the row circuit 330 and transfer it to the access operation circuit 350. The access operation circuit 350 may update the number of accesses by increasing the number of accesses and transfer the updated number of accesses to the column circuit 340. Also, the column circuit 340 may write the updated number of accesses into the memory cells of the N particular columns of the selected row. By the counting operation, the number of accesses to the row for which an active operation is currently being performed may be increased and stored. When the updated number of accesses is equal to or greater than the threshold value, the row classification circuit 360 may classify and store the neighboring rows of the currently active row as rows required to be refreshed.

A counting command for directing a counting operation may be defined as a new command which is different from existing commands (e.g., an active command, a read command, and a write command). Namely, the counting command may be defined as a new command in a command truth table. Also, the counting command may be defined based on the existing command. As a first example, when a predetermined particular column address (e.g., a column address corresponding to N particular columns) is applied along with a write command from the memory controller 210, the memory 250 may recognize it as a counting command. As a second example, when a predetermined particular column address is applied along with a read command from the memory controller 210, the memory 250 may recognize it as a counting command. To sum up, the counting command for directing a counting operation may be defined as a new command which is different from the existing command, defined as a combination of a write command and a particular column address, or defined as a combination of a read command and a particular column address.

According to how a memory system is designed, when a counting command is applied, the memory 250 may perform a counting operation in response to the counting command, and after the counting operation is completed, the memory 250 may also perform a precharge operation of the corresponding row as well. That is, the counting command may be determined to direct a counting operation and a precharge operation of the memory 250.

Refresh Operation

A refresh operation may begin as the memory controller 210 applies a refresh command to the memory 250. The row circuit 330 may refresh a row corresponding to a refresh row address among the rows of the cell array 320. The refresh row address may not be a row address transferred from the memory controller 210, but may be a row address generated internally in the memory 250.

The refresh operation may include an operation of activating a row and precharging the activated row. While the row is activated, data in the memory cells of the activated row may be sensed and amplified (i.e., re-written).

Smart Refresh Operation

A smart refresh operation may refer to an operation of refreshing a row whose data are likely to be lost due to a row hammering attack. A smart refresh operation may be performed by a direction of the memory controller 210 or it may be performed by the memory 250 itself. When the memory controller 210 directs the memory 250 to perform a smart refresh operation, the memory 250 may perform a smart refresh operation. Also, even though there is no direction from the memory controller 210, the memory 250 may perform a smart refresh operation in a spare time during a normal refresh operation.

During a smart refresh operation, the row circuit 330 may refresh one row among the rows required to be refreshed that are stored in the row classification circuit 360 in the cell array 320. For example, when a 6^{th} row and an 8^{th} row are stored as the rows required to be refreshed in the row classification circuit 360, the row circuit 330 may refresh one of the 6^{th} row and the 8^{th} row. The row on which a smart refresh operation is performed may be deleted from the row classification circuit 360.

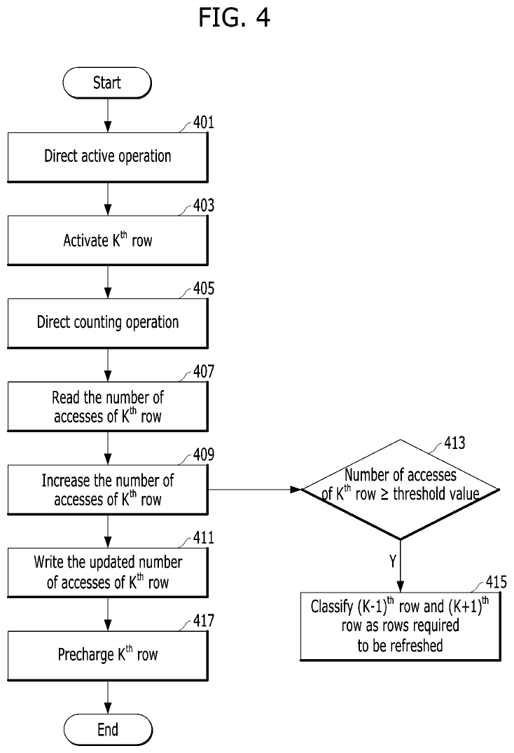

FIG. 4 is a flowchart describing an operation of the memory system 200 shown in FIG. 2 in accordance with an embodiment of the present invention. FIG. 4 illustrates operations related to a counting operation of the memory system 200.

Referring to FIG. 4, first, an active operation may be directed in operation 401. The active operation may be directed as the memory controller 210 transfers an active command and a row address to the memory 250.

A K^{th} row in the memory 220 may be activated in operation 403. The row circuit 330 of the memory 220 may activate a row (referred to as the K^{th} row) corresponding to a row address transferred from the memory controller 210 among the rows of the cell array 320.

A counting operation may be directed in operation 405. The counting operation may be directed as the memory controller 210 transfers a counting command to the memory 250. The counting command may be a newly defined command that is different from the existing commands, and the counting command may be defined as a combination of a write command and a particular column address, or it may be defined as a combination of a read command and a particular column address.

The number of accesses to the K^{th} row may be read in operation 407. The column circuit 340 may read the number of accesses which is stored in the memory cells of N particular columns of the K^{th} row and transfer the read number of accesses to the access operation circuit 350.

The number of accesses may be increased in operation 409. The access operation circuit 350 may increase the number of accesses to the K^{th} row by +1.

The updated number of accesses to the K^{th} row may be written in operation 411. The column circuit 340 may write the number of accesses which is updated by the access operation circuit into the memory cells of the N particular columns of the K^{th} row.

When the increased number of accesses is equal to or greater than a threshold value (Y in operation 413), the row classification circuit 360 may classify and store the neighboring rows of the K^{th} row, which are the (K+1)^{th} and (K−1)^{th} rows, as rows required to be refreshed in operation 415. Here, the rows required to be refreshed may mean rows whose data are likely to be lost due to a row hammering attack, and these rows may be refreshed during a smart refresh operation.

The K^{th} row may be precharged in operation 417). When the memory controller 210 applies a precharge command to the memory 250, the row circuit 330 may perform a precharge operation for terminating an active operation of the K^{th} row.

Other than the operations illustrated in FIG. 4, read operations and write operations may be further performed between an active operation 403 of the K^{th} row and a precharge operation 417 of the K^{th} row.

While the present invention has been described with respect to the specific embodiments, it will be apparent to those skilled in the art that various changes and modifications may be made without departing from the spirit and scope of the invention as defined in the following claims. Furthermore, the embodiments may be combined to form additional embodiments.

What is claimed is:

1. A method for operating a memory, comprising:
activating a row which is selected based on a row address among a plurality of rows;
receiving a counting command while the selected row is activated;
reading a number of accesses from memory cells of particular columns of the selected row in response to the counting command;
increasing the number of accesses; and
writing the increased number of accesses into the memory cells of the particular columns of the selected row.

2. The method of claim 1, further comprising:
detecting that the increased number of accesses is equal to or greater than a threshold value; and
classifying neighboring rows of the selected row as rows required to be refreshed in response to the detection.

3. The method of claim 2, further comprising:
determining to perform a smart refresh operation; and
refreshing at least one row among the rows required to be refreshed in response to the determination.

4. The method of claim 1, wherein data input from outside of the memory are not stored in the memory cells of the particular columns.

5. The method of claim 1, wherein the increasing of the number of accesses and the writing of the increased number of accesses into the memory cells of the particular columns of the selected row are performed in response to the counting command.

6. The method of claim 5, further comprising precharging the selected row, after the writing of the increased number of accesses into the memory cells of the particular columns of the selected row, in response to the counting command.

7. The method of claim 1, wherein the counting command comprises a read command and a particular column address.

8. The method of claim 1, wherein the counting command comprises a write command and a particular column address.

9. A memory, comprising:
a cell array including memory cells that are arranged in a plurality of rows and a plurality of columns;
a row circuit suitable for selecting and activating one row among the plurality of rows of the cell array during an active operation;
a column circuit suitable for reading a number of accesses from memory cells of particular columns of the selected row in response to a counting command, and writing an updated number of accesses to the memory cells of the particular columns of the selected row; and
an access operation circuit suitable for receiving the number of accesses which is read from the column circuit, increasing the number of accesses, and transferring the increased number of accesses to the column circuit as the updated number of accesses.

10. The memory of claim 9, further comprising a row classification circuit suitable for classifying neighboring rows of the selected row as rows required to be refreshed, when the updated number of accesses is equal to or greater than a threshold value.

11. The memory of claim 10, wherein during a smart refresh operation, a refresh operation is performed onto at least one row among the rows classified as required to be refreshed in the cell array.

12. The memory of claim 9, wherein data input from outside of the memory are not written into the memory cells of the particular columns.

13. The memory of claim 9, wherein the row circuit is further suitable for precharging the selected row, after the updated number of accesses is written in response to the counting command.

14. The memory of claim 9, wherein the counting command comprises a read command and a particular column address.

15. The memory of claim 9, wherein the counting command comprises a write command and a particular column address.

16. A method for operating a memory system, comprising:
transferring an active command and a row address from a memory controller to a memory;
activating, in the memory, a row corresponding to the row address;
transferring a counting command from the memory controller to the memory while the row is activated; and
increasing and writing a number of accesses to the row in the memory in response to the counting command.

17. The method of claim 16, wherein the increasing and writing of the number of accesses to the row in the memory in response to the counting command includes:
reading the number of accesses from memory cells of particular columns of the row;
increasing the number of accesses; and
writing the increased number of accesses into the memory cells of the particular columns of the row.

18. The method of claim 17, further comprising:
detecting, in the memory, that the increased number of accesses is equal to or greater than a threshold value; and
classifying neighboring rows of the row as rows required to be refreshed in response to the detection.

19. The method of claim 18, further comprising:
determining, in the memory, to perform a smart refresh operation; and
refreshing, in the memory, at least one row among the rows required to be refreshed in response to the determination.

20. The method of claim 16, wherein the transferring is performed whenever the activating is performed.

21. The method of claim 16, wherein the counting command comprises a read command and a particular column address.

22. The method of claim 16, wherein the counting command comprises a write command and a particular column address.

23. A memory system, comprising:
a memory controller suitable for directing an active operation and directing a counting operation during the active operation; and
a memory suitable for activating one row among a plurality of rows in response to the direction of the active operation, and increasing and writing a number of accesses to the row in response to the direction of the counting operation.

24. The memory system of claim 23, wherein the memory includes:
a cell array including memory cells that are arranged in the plurality of rows and a plurality of columns;
a row circuit suitable for activating the row in response to the direction of the active operation;
a column circuit suitable for reading the number of accesses from memory cells of particular columns of the row and writing an updated number of accesses into the memory cells of the particular columns of the row in response to the direction of the counting operation; and
an access operation circuit suitable for receiving the number of accesses which is read from the column circuit, increasing the number of accesses, and transferring the increased number of accesses to the column circuit as the updated number of accesses.

25. The memory system of claim 23, wherein the memory controller directs the counting operation at every active operation of the memory.

26. A memory comprising:
a memory cell array of rows each including one or more memory cells configured to store therein a number of accesses to the row; and
a control circuit configured to:
activate a selected one of the rows,
update the number stored in the selected row in response to a command, and
perform, when the updated number becomes a threshold or greater, a refresh operation on one or more adjacent rows of the selected row.
